(19) United States
(12) Patent Application Publication
(10) Pub. No.: US 2005/0036580 A1
(43) Pub. Date: Feb. 17, 2005

(54) Programmable phase-locked loop fractional-N frequency synthesizer

(76) Inventor: Ram Singh Rana, Singapore (SG)

Correspondence Address: NATH & ASSOCIATES, 1030 15th STREET, NW, 6TH FLOOR, WASHINGTON, DC, 20005, US

(21) Appl. No.: 10/638,336

(22) Filed: Aug. 12, 2003

(51) Int. Cl. H03D 3/24

(52) U.S. Cl. 375/376

(57) ABSTRACT

A fractional-N PLL with programmable fractionality having a phase detector and an oscillator is disclosed. The phase detector is for receiving a reference signal having a reference frequency and the oscillator is for providing an output signal having an output frequency. The fractional-N PLL comprises a divider for performing frequency divisions by applying selectable divisors, the divider being disposed in the loop of the fractional-N PLL for receiving the output signal from the oscillator and in response thereto provide a first signal having an averaged frequency. The fractional-N PLL also comprises a first counter connected to the divider in the loop of the fractional-N PLL for receiving the first signal, the first counter for performing a first plurality of counts to a predetermined first integer in response to the averaged frequency of the first signal, wherein the first counter provides a second signal having a loop frequency in accordance with the first plurality of counts to the phase detector for providing the detection of the phase difference between the reference signal and the second signal.

### FIELD OF INVENTION

The invention relates generally to frequency synthesizers. In particular, the invention relates to frequency synthesizers applying a fractional-N phase-locked loop (PLL).

### BACKGROUND

Frequency synthesizers applying a fractional-N PLL have many applications, especially in relation to communication systems which typically have low phase noise requirements. This is because through use of the fractional-N configuration, the fractional-N PLL is able to operate with low phase noise by making reference frequency higher than step size.

To meet operational requirements for different applications features of the fractional-N PLL such as the relationship between reference frequency and step size and the division ratio of output and reference frequencies may vary. Therefore, frequency synthesizers using the fractional-N PLL with programmability of such features are required.

To this end, a number of fractional-N PLLs have been proposed for application in frequency synthesizers. A block diagram of a typical conventional fractional-N PLL 102 used in a frequency synthesizer is shown in FIG. 1. The fractional-N PLL 102 consists of a phase frequency detector (PFD) 104, a loop filter (LPF) 106, a voltage-controlled oscillator (VCO) 108, a modulus divider (N/(N+1)) 110 and a modulus controller 112 provided with a control word K 114 as input. The inputs to the PFD 104 are signals with a reference frequency, Fᵣ, 116 from a reference source and a frequency, F_{d}, 118 from the modulus divider 110. The difference of these two frequencies are detected by the PFD 104 which in response provides a corresponding equivalent control voltage that is filtered by the LPF 106. The filtered control voltage is provided as input to the VCO 108 which in turn generates a signal with an output frequency, Fₒ, 120 such that frequency difference (Fᵣ-F_{d}) approaches zero. The modulus divider 110 divides by N when a mode signal 122 provided as input by the modulus controller 112 is low and by (N+1) when the mode signal 122 is high. The frequency of occurrence of the mode signal 122 in the high state is determined by the requirements of the frequency synthesizer for the output frequency, Fₒ, for a given reference frequency, Fᵣ. The minimum frequency difference of two adjacent output frequencies is generally termed as step size of the frequency synthesizer. In the conventional configuration of the fractional-N PLL 102, the control word K 114, which is n-bit long and provided as input to the modulus controller 112, determines the frequency of occurrence of the mode signal 122 in the high state. The operation of the fractional-N PLL 102 is governed by the following relationships:
1. Step size=Fᵣ* (1/2ⁿ)
2. Minimum output frequency Fₒₘᵢₙ=Fᵣ* N
3. Maximum output frequency Fₒₘₐₓ=Fᵣ* (N+1)
4. Fₒ=Fᵣ* Nₐᵥ, where Fₒ is output frequency and Nₐᵥ is average division ratio
5.

$$\begin{matrix}{N}_{av} = [ K ( N + 1 ) + ( {2}^{n} - K ) N ] / {2}^{n} \\ = ( N + K / {2}^{n} ) ; 0 < K / {2}^{n} < 1\end{matrix}$$

In the fractional-N PLL 102, however, the step size is limited by hardware used for providing the control word K 114 to the modulus controller 112.

Another proposal for a fractional-N PLL 202 described in “A Low Phase Noise C-Band Synthesizer Using A New Fractional-N PLL with Programmable Fractionality” by T. Nakagawa and T Tsukahara, IEEE Trans. On Microwave Theory and Techniques, Vol. 44, No. 2, February 1996, pp 344-346, is shown in FIG. 2. The fractional-N PLL 202 consists of a phase frequency detector (PFD) 204, a loop filter (LPF) 206, a voltage-controlled oscillator (VCO) 208, a modulus divider (N/(N+1)) 210, a control logic unit 212, an M-counter 211 and an A-counter 215. The inputs to the PFD 204 are signals with a reference frequency, Fᵣ, 216 from a reference source and a frequency, F_{d}, 218 from the modulus divider 210. The difference of these two frequencies are detected by the PFD 204 which in response provides a corresponding equivalent control voltage that is filtered by the LPF 206. The filtered control voltage is provided as input to the VCO 208 which in turn generates a signal with an output frequency, Fₒ, 220 such that frequency difference (Fᵣ-F_{d}) approaches zero. The modulus divider 210 divides by N when a mode signal 222 provided as input by the control logic unit 212 is low and by (N+1) when the mode signal 222 is high.

The output of the modulus divider 210 is also provided as inputs to the M-counter 211 and the A-counter 215, which respectively perform counts for each pulse of the signal having the divider frequency, F_{d}, 218 from the modulus divider 210. The respective outputs of the M-counter 211 and A-counter 215 are provided as trigger inputs to the control logic unit 212 which in response provides logic control resulting in the generation of the mode signal 222, which in turn determines the frequency of occurrence of the mode signal 222 in the high state.

In the modulus divider 210 the division ratio, Nₐᵥ, equals (N+A/M) where the integers M and A are programmable respectively in accordance with the programming of the M-counter 211 and the A-counter 215. Hence the step size of the fractional-N PLL 202, which is related to the ratio A/M, is programmable. Since the division ratio, Nₐᵥ, is affected by the ratio A/M, it is therefore also programmable.

The operation of the fractional-N PLL 202 is governed by the following relationships:
1. Step size=Fᵣ* (A/M)
2. Minimum output frequency Fₒₘᵢₙ=Fᵣ* N
3. Maximum output frequency Fₒₘₐₓ=Fᵣ* (N+1)
4. Fₒ=Fᵣ* Nₐᵥ, where Fₒ is output frequency and Nₐᵥ is average division ratio
5. Nₐᵥ=(N+A/M); 0<A/M<1, A<M

Although in the fractional-N PLL the step size is programmable, the value of integer N limits the maximum value of average division ratio Nₐᵥ to N+1 only, which in turn limits the output frequency to within a non-programmable range (Fₒₘₐₓ-Fₒₘᵢₙ).

Accordingly there is therefore a need for a fractional-N PLL for a frequency synthesizer for addressing the foregoing limitations of conventional fractional-N PLLs.

### SUMMARY

Embodiments of the invention are disclosed herein relating to a fractional-N PLL which is based on a scheme in which the control of a modulus divider is limited to the use of counters. In these embodiments step size is programmable by adjusting counter values. Additionally, the division ratio of the modulus divider is programmable and is not limited by the modulus factor of the modulus divider. The architecture of such embodiments is also simple as hardware is not required either for input data word processing or for control logic to generate a mode signal to control the modulus factor of the modulus divider. In the architecture of the embodiments, the output of one of the counters functions as a mode signal to control the modulus factor of the modulus divider.

The embodiments may also include noise shaping for compensating phase errors generated in relation to fractional division performed by the modulus divider. Digital output from the modulus divider may be used as input to a noise shaping circuit which in turn may generate output for compensating the phase errors.

In accordance with a first aspect of the invention, there is disclosed a fractional-N PLL in a frequency synthesizer with programmable fractionality having a phase detector and an oscillator, the phase detector for receiving a reference signal having a reference frequency and the oscillator for providing an output signal having an output frequency. The fractional-N PLL comprises a divider for performing frequency divisions by applying selectable divisors, the divider being disposed in the loop of the fractional-N PLL for receiving the output signal from the oscillator and in response thereto provide a first signal having an averaged frequency; and a first counter connected to the divider in the loop of the fractional-N PLL for receiving the first signal, the first counter for performing a first plurality of counts to a predetermined first integer in response to the averaged frequency of the first signal, wherein the first counter provides a second signal having a loop frequency in accordance with the first plurality of counts to the phase detector for providing the detection of the phase difference between the reference signal and the second signal.

In accordance with a second aspect of the invention, there is disclosed in a frequency synthesizer having a fractional-N PLL with programmable fractionality a method by which the fractional-N PLL operates, the fractional-N PLL having a phase detector and an oscillator, the phase detector for receiving a reference signal having a reference frequency and the oscillator for providing an output signal having an output frequency. The method comprises the steps of performing frequency divisions using a divider by applying selectable divisors, the divider being disposed in the loop of the fractional-N PLL for receiving the output signal from the oscillator and in response thereto provide a first signal having an averaged frequency; and receiving the first signal by a first counter connected to the divider in the loop of the fractional-N PLL, the first counter for performing a first plurality of counts to a predetermined first integer in response to the averaged frequency of the first signal, wherein the first counter provides a second signal having a loop frequency in accordance with the first plurality of counts to the phase detector for providing the detection of the phase difference between the reference signal and the second signal.

### BRIEF DESCRIPTION OF DRAWINGS

Embodiments of the invention are described hereinafter in detail with reference to the drawings, in which:

FIG. 1 is a block diagram of a conventional fractional-N PLL;

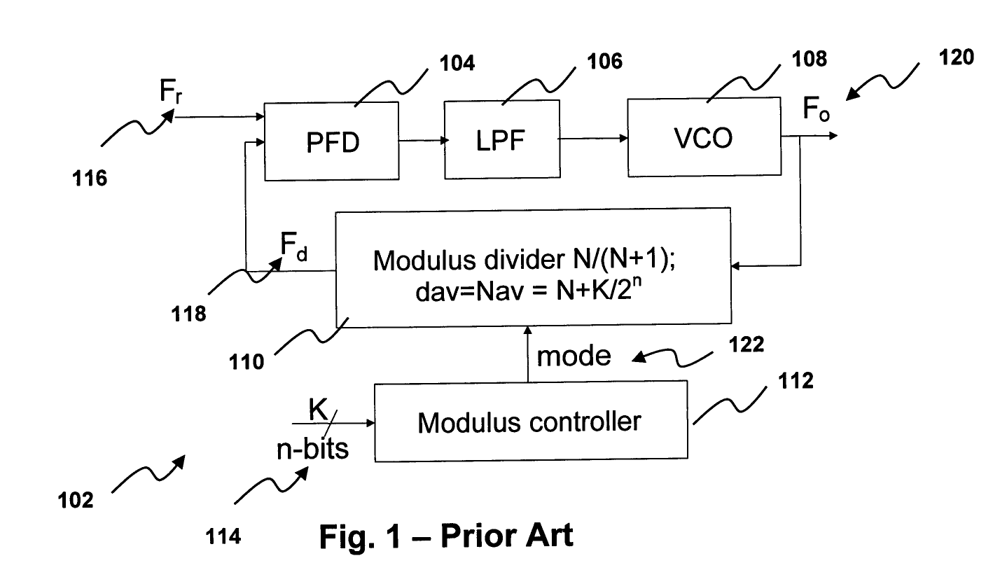

FIG. 2 is a block diagram of alternate conventional fractional-N PLL;

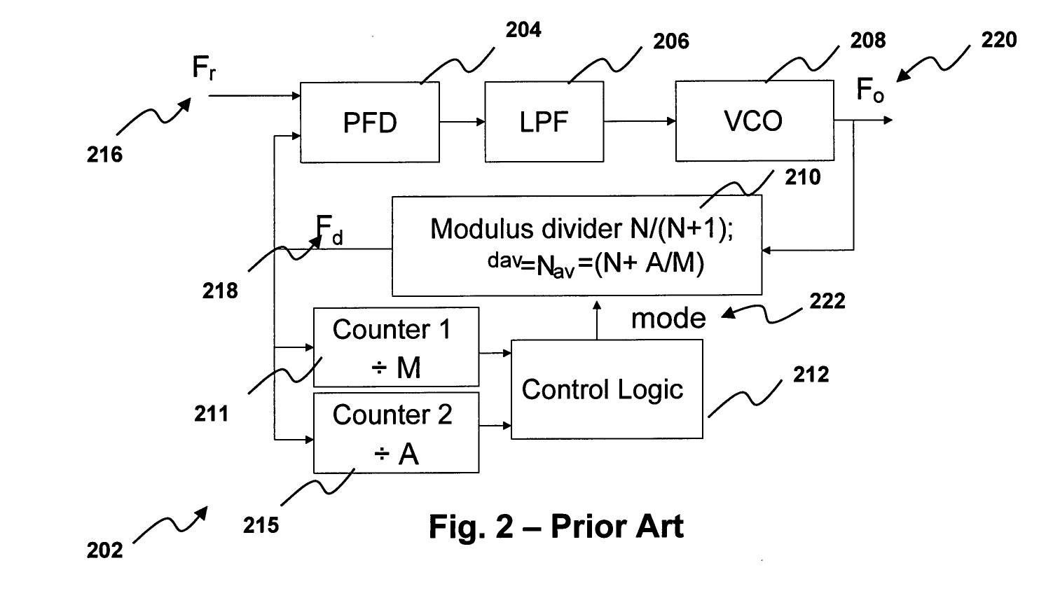

FIG. 3 is a block diagram of a fractional-N PLL according to a preferred embodiment of the invention;

FIG. 4 is a flowchart of the fractional-N operation of the fractional-N PLL in FIG. 3; and

FIG. 5 is a block diagram of a fractional-N PLL according to an alternate embodiment of the invention.

### DETAILED DESCRIPTION

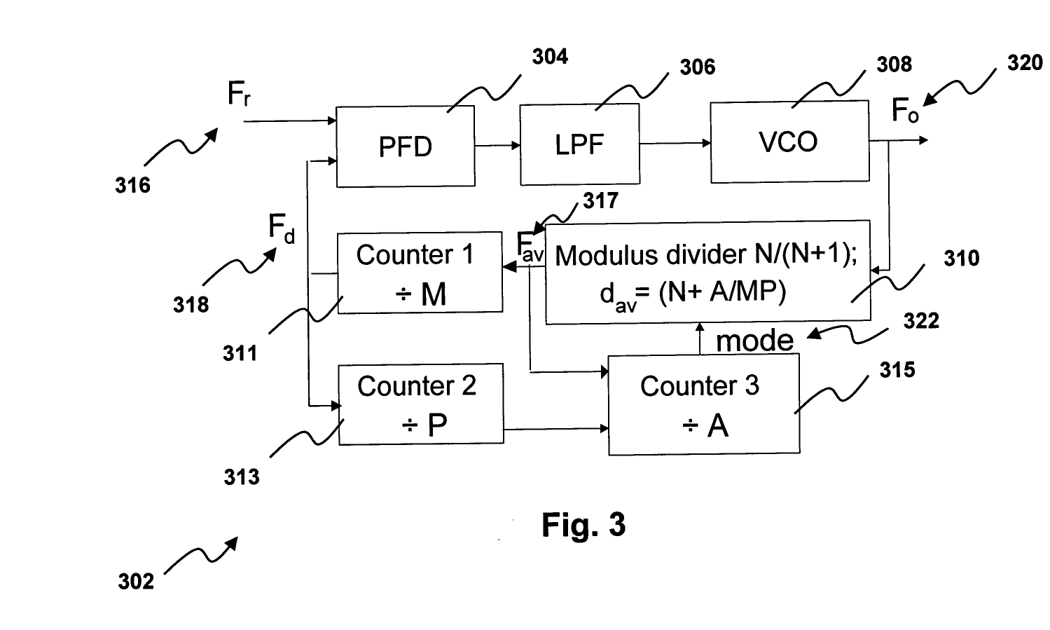

Embodiments of the invention are described in detail hereinafter with reference to FIGS. 3 to 5 for addressing the need for fractional-N PLLs for frequency synthesizers for addressing the foregoing limitations of conventional fractional-N PLLs.

The advantages of the embodiments are manifold. These include the embodiments not requiring any hardware other than counters for controlling a modulus divider in a fractional-N PLL and the fractional-N PLL having programmable step size. Step size is programmable in the fractional-N PLL by the setting of the ratio of counters in the fractional-N PLL. The advantages also include the fractional-N PLL having high division ratio with programmability thereby helping the generation of high output frequencies from a very low reference frequency with fine resolution in step size. The advantages further include the fractional-N PLL having flexibility in programming the division ratio and a simple system topology compared to that of conventional fractional-N PLLs using control words. The advantages still further include the control of the modulus divider in the fractional-N PLL being generated using the counters without using additional circuitry for providing a modulus controller. The advantages even further include the use of noise shaping for compensating phase errors generated in relation to fractional division performed by the modulus divider.

A block diagram of a fractional-N PLL 302 according to a preferred embodiment of the invention is described with reference to FIG. 3. The fractional-N PLL 302 advantageously consists of only three counters for determining the division ratio, where all the counters are programmable.

Specifically, the fractional-N PLL 302 consists of a phase frequency detector (PFD) 304, a loop filter (LPF) 306, a voltage-controlled oscillator (VCO) 308, a modulus divider (N/(N+1)) 310, an M-counter 311, a P-counter 313 and an A-counter 315. The inputs to the PFD 304 are signals with a reference frequency, Fᵣ, 316 from a reference source and a loop frequency, F_{d}, 318 from the M-counter 311. The difference of these two frequencies are detected by the PFD 304 which in response provides a corresponding equivalent control voltage that is filtered by the LPF 306. The filtered control voltage is provided as input to the VCO 308 which in turn generates a signal with an output frequency, Fₒ, 320 such that frequency difference (Fᵣ-F_{d}) approaches zero. The modulus divider 310 divides by N when a mode signal 322 provided as trigger input by the A-counter 315 is low and by (N+1) when the mode signal 322 is high.

The output of the modulus divider 310 is provided as count inputs to the M-counter 311 and the A-counter 315, which respectively perform counts for each pulse of a signal having an averaged frequency, Fₐᵥ, 317 from the modulus divider 310. The output signal having the loop frequency, F_{d}, 318 from the M-counter 311 is also provided as a count input to the P-counter 313, which in turn provides a trigger input to the A-counter 315, which in turn determines the frequency of occurrence of the mode signal 322 in the high state.

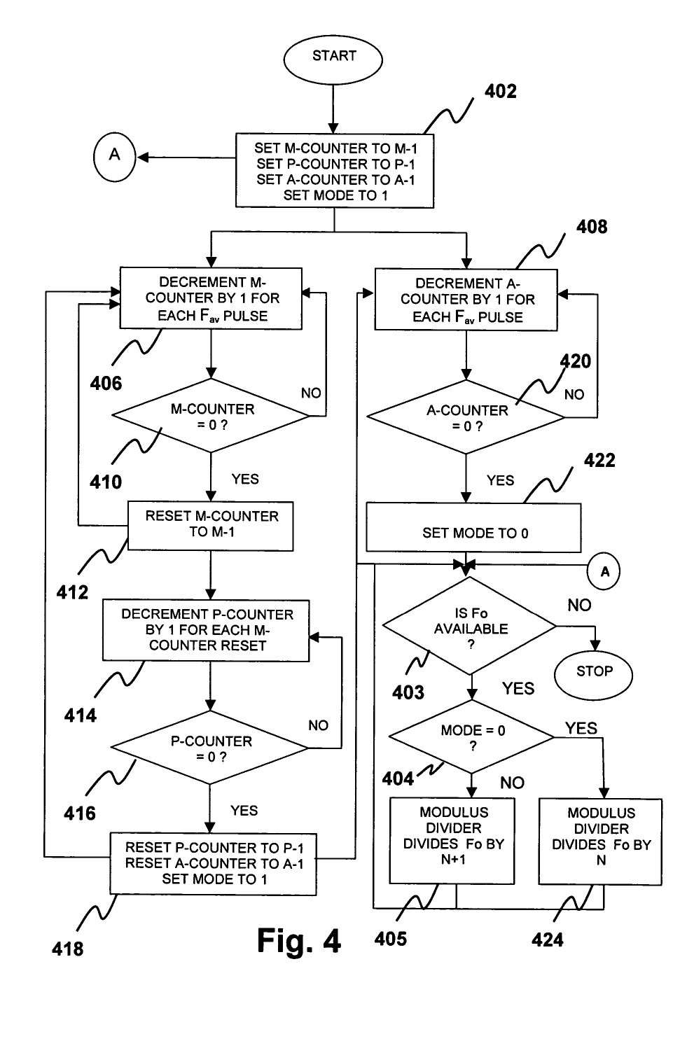

A flowchart is shown in FIG. 4 for providing a detailed description of the operation of the modulus divider (N/(N+1)) 310, the M-counter 311, the P-counter 313 and the A-counter 315 in the fractional-N configuration.

In a step 402, the M-, P-, and A-counters (311, 313 and 315 respectively) are initially set to M-1, P-1 and A-1 respectively and the mode signal 322 is set high and remains high until the A-counter 315 counts down to zero in a subsequent step. During operation when the mode signal 322 is set high in a step 418 and the output frequency, Fₒ, 320 is checked that it is available in a step 403 and the mode signal 322 is checked that it is not low in a step 404, the modulus divider 310 performs division using the modulus factor (N+1) in a step 405. If the output frequency, Fₒ, 320 is not available the counting operation stops.

The M- and A-counters (311 and 315 respectively) continuously count down the pulse cycles of the signal having the averaged frequency, Fₐᵥ, available at the output of modulus divider 310 in respective steps 406 and 408.

During the counting operation of the M-counter 311 beginning with the step 406, the signal having the loop frequency of F_{d}=Fₐᵥ/M is provided as an input to the PFD 304 by the M-counter 311. When the M-counter 311 reaches zero as determined in a step 410, the M-counter 311 resets again to M-1 in a step 412 and a pulse in the signal having the loop frequency of F_{d}=Fₐᵥ/M reaches the P-counter 313 so that the P-counter 313 counts down according to the pulse received from the M-counter 311 in a step 414. Once the P-counter 313 reaches zero as determined in a step 416 the P-counter 313 resets to P-1, resets A-counter to A-1, and sets the mode signal 322 to high again in the step 418. The counting operation of the M-counter 311 then loops back to the step 406. Also when the mode signal 322 is set high in the step 418 and the output frequency, Fₒ, 320 is checked that it is available in the step 403 and the mode signal 322 is checked that it is not low in the step 404, the modulus divider 310 performs division using the modulus factor (N+1) in the step 405. If the output frequency, Fₒ, 320 is not available the counting operation stops. The step 418 further proceeds to the step 408 where the counting operation of the A-counter 315 begins.

During the counting operation of the A-counter 315 beginning with the step 408, once the A-counter 315 reaches zero as determined in a step 420, the mode signal 322 is set to low in a step 422 and the output frequency, Fₒ, 320 is checked that it is available in the step 403 and the mode signal 322 is checked that it is low in the step 404, the modulus divider 310 performs division using the modulus factor N in a step 424. If the output frequency, Fₒ, 320 is not available the counting operation stops.

As a result, the modulus divider 310 for A-times divides the output frequency, Fₒ, 320 by (N+1) and for (MP-A)-times divides the output frequency, Fₒ, 320 by N during each MP pulse cycles of the output frequency, Fₒ, 320. The operation of the fractional-N PLL 302 is governed by the following relationships:
1. Step size=Fᵣ* (A/P)
2. Minimum output frequency Fₒₘᵢₙ=Fᵣ* MN
3. Maximum output frequency Fₒₘₐₓ=Fᵣ* (MN+1)
4. Fₒ=Fᵣ* Nₐᵥ, where Nₐᵥ is average division ratio of PLL loop
5.

$$\begin{matrix}{N}_{av} = M [ ( ( N + 1 ) A + N ( MP - A ) ) / MP ] \\ = M ( N + A / MP ) \\ = ( MN + A / P ) ; 0 < A / P < 1\end{matrix}$$
6. Average modulus division of modulus divider dₐᵥ=N+A/MP

In the modulus divider 317 a desired division ratio, dₐᵥ can be adjusted by programming the M-counter 311 by which a desired loop division ratio Nₐᵥ can be achieved. This enables the application of the fractional-N PLL 302 in a frequency synthesizer to high frequencies generation using a very low reference frequency compared to the conventional fractional-N PLLs used in conventional frequency synthesizers. The desired output frequency range can therefore be achieved by programming the M-counter 311.

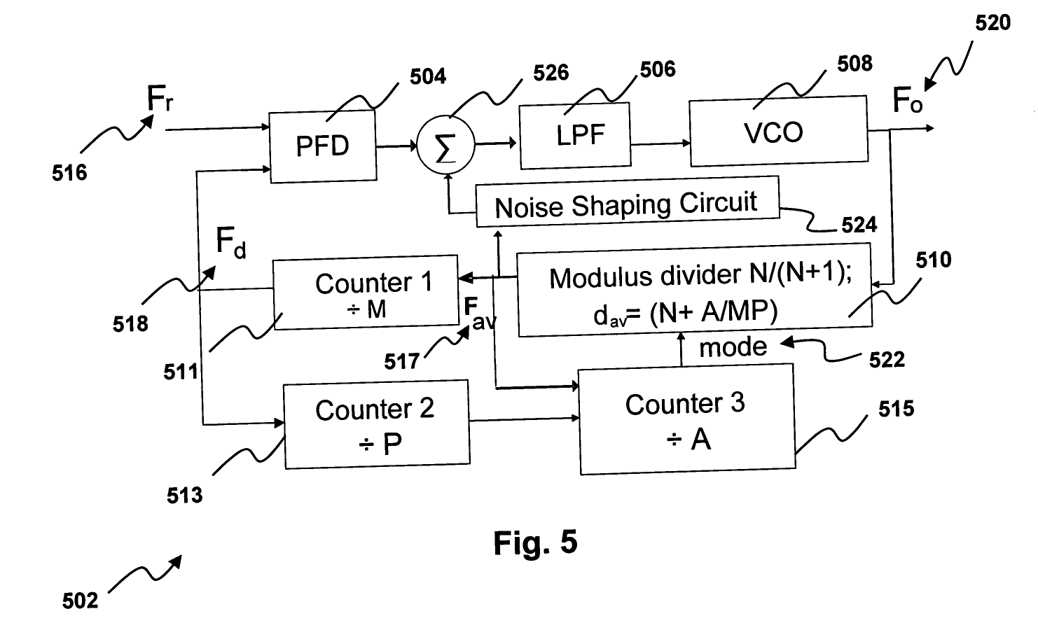

A block diagram of a fractional-N PLL 502 according to an alternate embodiment of the invention is described with reference to FIG. 5. The fractional-N PLL 502 in the PLL loop advantageously consists of only three counters for determining the division ratio, where all the counters are programmable, and a noise-shaping module.

Specifically, the fractional-N PLL 502 consists of a phase frequency detector (PFD) 504, a loop filter (LPF) 506, a voltage-controlled oscillator (VCO) 508, a modulus divider (N/(N+1)) 510, an M-counter 511, a P-counter 513, an A-counter 515, a noise shaping circuit 524, and a summer 526. The inputs to the PFD 504 are signals with a reference frequency, Fᵣ, 516 from a reference source and a loop frequency, F_{d}, 518 from the M-counter 511. The difference of these two frequencies are detected by the PFD 504 which in response provides a corresponding equivalent control voltage that is summed by the summer 526 with the output of the noise shaping circuit 524, the summed voltage consequently being filtered by the LPF 506. The filtered voltage is provided as input to the VCO 508 which in turn generates a signal with an output frequency, Fₒ, 520 such that frequency difference (Fᵣ-Fₗ) approaches zero. The modulus divider 510 divides by N when a mode signal 522 provided as trigger input by the A-counter 515 is low and by (N+1) when the mode signal 522 is high.

The output of the modulus divider 510 is provided as count inputs to the M-counter 511 and the A-counter 515, which respectively perform counts for each pulse of a signal having an averaged frequency, Fₐᵥ, 517 from the modulus divider 510. The output signal having the loop frequency, F_{d}, 518 from the M-counter 511 is also provided as a count input to the P-counter 513 which in turn provides a trigger input to the A-counter 515, which in turn determines the frequency of occurrence of the mode signal 522 in the high state.

The noise shaping circuit 524 also receives from the modulus divider 510 the signal having the averaged frequency, Fₐᵥ, 517 and performs noise shaping or phase error compensation thereon. The output of the noise shaping circuit is then provided as input to the summer 526 for summing with the output of the PFD 504 for providing a further signal to compensate the phase error.

The noise shaping circuit 524 may comprise of a digital-to-analog convertor (DAC) whereby the noise shaping performance of the noise shaping circuit 524 depends on the accuracy of the DAC. The noise shaping circuit 524 may alternatively comprise of a sigma-delta modulator whereby the noise shaping performing of the noise shaping circuit 524 depends on the order of the sigma-delta modulator.

The DAC-based noise shaping circuit 524 is preferred because it can provide an analog output from a digital input obtained from the modulus divider 510 whereas the sigma-delta modulator-based noise shaping circuit 524 is more complicated as it provides a digital output which has to be converted to analog form for input to the summer 526.

In the foregoing manner, there are described fractional-N PLLs advantageously consisting of only three counters for determining the division ratio, where all the counters are programmable. Although only a number of embodiments of the invention are disclosed, it becomes apparent to one skilled in the art in view of this disclosure that numerous changes and/or modification can be made without departing from the scope and spirit of the invention.

1. In a frequency synthesizer a fractional-N PLL with programmable fractionality having a phase detector and an oscillator, the phase detector for receiving a reference signal having a reference frequency and the oscillator for providing an output signal having an output frequency, the fractional-N PLL comprising:
a divider for performing frequency divisions by applying selectable divisors, the divider being disposed in the loop of the fractional-N PLL for receiving the output signal from the oscillator and in response thereto provide a first signal having an averaged frequency; and
a first counter connected to the divider in the loop of the fractional-N PLL for receiving the first signal, the first counter for performing a first plurality of counts to a predetermined first integer in response to the averaged frequency of the first signal, wherein the first counter provides a second signal having a loop frequency in accordance with the first plurality of counts to the phase detector for providing the detection of the phase difference between the reference signal and the second signal.

2. The fractional-N PLL as in claim 1, wherein upon performing a count in the first plurality of counts to the first integer the first counter resets the count in the first plurality of counts.

3. The fractional-N PLL as in claim 2, further comprising a second counter connected to the first counter for receiving the second signal and performing a second plurality of counts to a predetermined second integer in response to the loop frequency of the second signal, wherein upon performing a count in the second plurality of counts to the second integer the second counter generates a third signal and resets the count in the second plurality of counts.

4. The fractional-N PLL as in claim 3, further comprising a third counter connected to the divider for receiving the first signal and performing a third plurality of counts in response to the averaged frequency of the first signal to a predetermined third integer, wherein upon performing a count in the third plurality of counts to the third integer the third counter generates a first state for a fourth signal, wherein the third counter is further connected to the second counter for receiving the third signal and in response to the third signal the third counter resets the count in the third plurality of counts and generates a second state for the fourth signal, and wherein the first state for the fourth signal is receivable by the divider for selecting one of the selectable divisors and the second state for the fourth signal is receivable by the divider for selecting another of the selectable divisors.

5. The fractional-N PLL as in claim 4, wherein the divider is a modulus divider.

6. The fractional-N PLL as in claim 5, wherein the modulus divider performs frequency division by applying one of selectable integers N and N+1.

7. The fractional-N PLL as in claim 6, wherein when the first state for the fourth signal is received by the modulus divider the modulus divider performs frequency division by applying the selectable integer N and when the second state for the fourth signal is received by the modulus divider the modulus divider performs frequency division by applying the selectable integer N+1.

8. The fractional-N PLL as in claim 7, wherein the relationship between the reference signal and the output signal during operation of the fractional-N PLL is according to:
Fₒ/Fᵣ=(MN+A/P)
wherein Fₒ represents the output frequency of the output signal, Fᵣ represents the reference frequency of the reference signal, M represents the first integer, P represents the second integer, and A represents the third integer.

9. The fractional-N PLL as in claim 4, further comprising noise-shaping means connected to the modulus divider for receiving the first signal and performing noise shaping thereon.

10. The fractional-N PLL as in claim 9, further comprising a summer whereto the phase detector and the noise-shaping means are connected for summing the outputs of the phase detector and the noise-shaping means for canceling phase noise generated due to fractional division performed by the divider.

11. In a frequency synthesizer having a fractional-N PLL with programmable fractionality a method by which the fractional-N PLL operates, the fractional-N PLL having a phase detector and an oscillator, the phase detector for receiving a reference signal having a reference frequency and the oscillator for providing an output signal having an output frequency, the method comprising the steps of:
performing frequency divisions using a divider by applying selectable divisors, the divider being disposed in the loop of the fractional-N PLL for receiving the output signal from the oscillator and in response thereto provide a first signal having an averaged frequency; and
receiving the first signal by a first counter connected to the divider in the loop of the fractional-N PLL, the first counter for performing a first plurality of counts to a predetermined first integer in response to the averaged frequency of the first signal, wherein the first counter provides a second signal having a loop frequency in accordance with the first plurality of counts to the phase detector for providing the detection of the phase difference between the reference signal and the second signal.

12. The method as in claim 11, wherein the step of receiving the first signal comprises the step of performing a count in the first plurality of counts to the first integer and generating by the first counter a second signal and resetting the count in the first plurality of counts.

13. The method as in claim 12, further comprising the step of receiving the second signal by a second counter connected to the first counter and performing a second plurality of counts to a predetermined second integer in response to the loop frequency of the second signal, wherein upon performing a count in the second plurality of counts to the second integer the second counter generates a third signal and resets the count in the second plurality of counts.

14. The method as in claim 13, further comprising the step of receiving the first signal by a third counter connected to the divider and performing a third plurality of counts in response to the averaged frequency of the first signal to a predetermined third integer, wherein upon performing a count in the third plurality of counts to the third integer the third counter generates a first state for a fourth signal, wherein the third counter is further connected to the second counter for receiving the third signal and in response to the third signal the third counter resets the count in the third plurality of counts and generates a second state for the fourth signal, and wherein the first state for the fourth signal is receivable by the divider for selecting one of the selectable divisors and the second state for the fourth signal is receivable by the divider for selecting another of the selectable divisors.

15. The method as in claim 14, wherein the step of performing frequency divisions comprises the step of performing frequency divisions using a modulus divider.

16. The method as in claim 15, wherein the step of performing frequency divisions using the modulus divider comprises the step of performing frequency division by applying one of selectable integers N and N+1.

17. The method as in claim 16, further comprising the step of performing frequency division by the modulus divider by applying the selectable integer N when the first state for the fourth signal is received by the modulus divider and performing frequency division by the modulus divider by applying the selectable integer N+1 when the second state for the fourth signal is received by the modulus divider.

18. The method as in claim 17, further comprising the step of providing a relationship between the reference signal and the output signal during operation of the fractional-N PLL according to:
Fₒ/Fᵣ=(MN+A/P)
wherein Fₒ represents the output frequency of the output signal, Fᵣ represents the reference frequency of the reference signal, M represents the first integer, P represents the second integer, and A represents the third integer.

19. The method as in claim 14, further comprising the step of performing noise shaping on the first signal by noise-shaping means connected to the divider for receiving the first signal.

20. The method as in claim 19, further comprising the step of summing by a summer, whereto the phase detector and the noise-shaping means are connected, the outputs of the phase detector and the noise-shaping means for canceling phase noise generated due to fractional division performed by the divider.
